(19) United States
(12) Patent Application Publication
(10) Pub. No.: US 2013/0234282 A1
(43) Pub. Date: Sep. 12, 2013

(54) SEMICONDUCTOR DEVICE WITH VERTICAL CELLS AND FABRICATION METHOD THEREOF

(71) Applicant: SK HYNIX INC., Gyeonggi-do (KR)

(72) Inventor: Jung-Woo PARK, Gyeonggi-do (KR)

(73) Assignee: SK hynix Inc., Gyeonggi-do (KR)

(21) Appl. No.: 13/872,520

(22) Filed: Apr. 29, 2013

Related U.S. Application Data
(62) Division of application No. 12/830,654, filed on Jul. 6, 2010.

(30) Foreign Application Priority Data
Dec. 30, 2009 (KR) 10-2009-0134732

(51) Int. Cl. H01L 29/06

(52) U.S. Cl. CPC H01L 29/0649
USPC 257/508

(57) ABSTRACT

A method for fabricating a semiconductor substrate includes defining an active region by forming a device isolation layer over the substrate, forming a first trench dividing the active region into a first active region and a second active region, forming a buried bit line filling a portion of the first trench, forming a gap-filling layer gap-filling an upper portion of the first trench over the buried bit line, forming second trenches by etching the gap-filling layer and the device isolation layer in a direction crossing the buried bit line, and forming a first buried word line and a second buried word line filling the second trenches, wherein the first buried word line and the second buried word line are shaped around sidewalls of the first active region and the second active region, respectively.

### CROSS-REFERENCE TO RELATED APPLICATIONS

The present application claims priority of Korean Patent Application No. 10-2009-0134732 filed on Dec. 30, 2009, which is incorporated herein by reference in its entirety.

### BACKGROUND OF THE INVENTION

Exemplary embodiments of the present invention relate to a semiconductor device, and more particularly, to a semiconductor device including vertical cells and a method for fabricating the same.

Because of some effect, e.g., a short channel effect of a MOS transistor, a general planar cell may have difficulty obtaining a sufficient active region. Thus, there may be a limitation on how small a cell may be formed.

As an alternative, a vertical cell, which includes a vertical gate, has been recently suggested.

FIG. 1A is a perspective view illustrating a known semiconductor device, and FIG. 1B is a plan view of the known semiconductor device illustrating vertical gates, buried bit lines, and word lines.

Referring to FIGS. 1A and 1B, active pillars 12 may be formed over a substrate 11, and vertical gates 15 may be formed to surround the sidewalls of an active pillar 12. Buried bit lines 16A and 16B may be formed in the substrate 11 through ion implantation. Also, a gate insulation layer 17 may be formed between the vertical gate 15 and the active pillar 12, and a protective layer 13 may be formed on top of the active pillars 12, and a capping layer 14 may be formed on the sidewalls of the active pillar 12 and the protective layer 13. Further, the protective layer 13 may include a nitride layer. Also, neighboring vertical gates 15 may be coupled with each other through word lines 18.

According to the above-described known vertical cell technology, it may be difficult to form the vertical cells because of the relatively small size of active pillars corresponding to active regions.

### SUMMARY OF THE INVENTION

Exemplary embodiments of the present invention are directed to a semiconductor device which may increase cell density, and a method for fabricating the semiconductor device.

Other exemplary embodiments of the present invention are directed to a semiconductor device which may achieve a smaller design rule, and a method for fabricating the semiconductor device.

In accordance with an exemplary embodiment of the present invention, a method for fabricating a semiconductor substrate includes defining an active region by forming a device isolation layer over a substrate, forming a first trench dividing the active region into a first active region and a second active region, forming a buried bit line filling a portion of the first trench, forming a gap-filling layer gap-filling an upper portion of the first trench over the buried bit line, forming second trenches by etching the gap-filling layer and the device isolation layer in a direction crossing the buried bit line, and forming a first buried word line and a second buried word line filling the second trenches, wherein the first buried word line and the second buried word line are shaped around sidewalls of the first active region and the second active region, respectively.

In accordance with another exemplary embodiment of the present invention, a semiconductor device includes a first active region and a second active region separated from each other by a trench, a buried bit line filling a portion of the trench, a first buried word line shaped around sidewalls of the first active region, and a second buried word line shaped around sidewalls of the second active region.

### BRIEF DESCRIPTION OF THE DRAWINGS

FIG. 1A is a perspective view illustrating a known semiconductor device.

FIG. 1B is a plan view of a known semiconductor device illustrating vertical gates, buried bit lines, and word lines.

FIG. 2A is a plan view illustrating a semiconductor device in accordance with an exemplary embodiment of the present invention.

FIG. 2B is a perspective view illustrating the semiconductor device in accordance with an exemplary embodiment of the present invention.

FIG. 2C is a cross-sectional view showing the semiconductor device of FIG. 2A cut along a line A-A′.

FIG. 2D is a cross-sectional view showing the semiconductor device of FIG. 2A cut along a line B-B′.

FIGS. 3A to 3J are plan views describing a method for fabricating a semiconductor device in accordance with an exemplary embodiment of the present invention.

FIGS. 4A, 4C, 4E, 4G, 4I, 4K, 4M, 4O, 4Q, and 4S are cross-sectional views showing the semiconductor device of FIGS. 3A to 3J cut along a line A-A′.

FIGS. 4B, 4D, 4F, 4H, 4J, 4L, 4N, 4P, 4R and 4T are cross-sectional views showing the semiconductor device of FIGS. 3A to 3J cut along a line B-B′.

FIG. 5 is a plan view illustrating a cell array of a semiconductor device fabricated in accordance with an exemplary embodiment of the present invention.

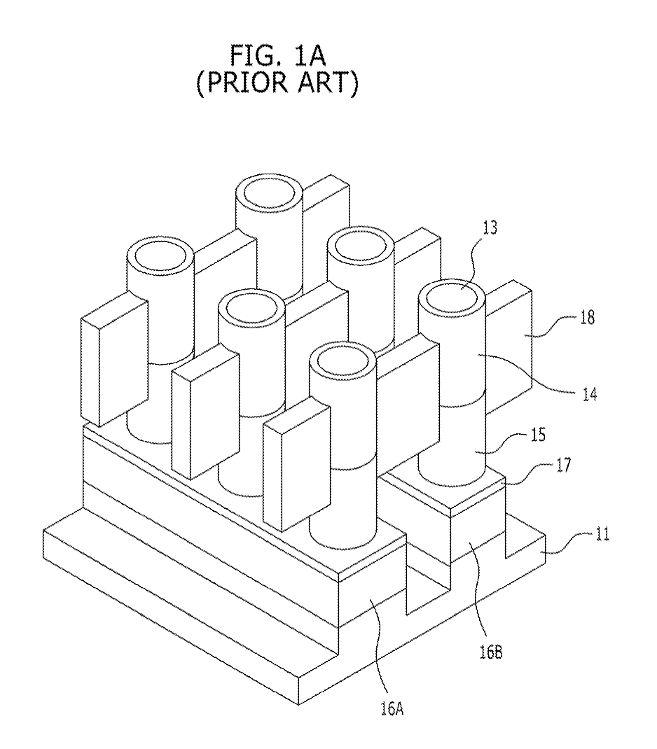

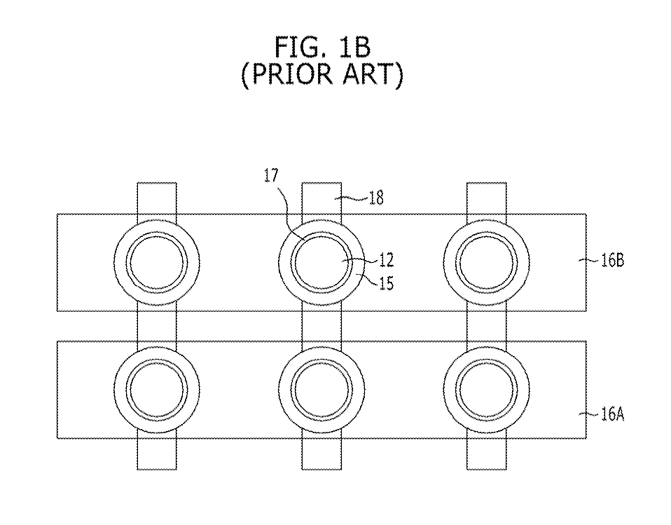

### DESCRIPTION OF SPECIFIC EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to dearly illustrate features of the embodiments. When a first layer is referred to as being “on” a second layer or “on” a substrate, it not only refers to a case where the first layer is formed directly on the second layer or the substrate, but also a case where a third layer exists between the first layer and the second layer or the substrate.

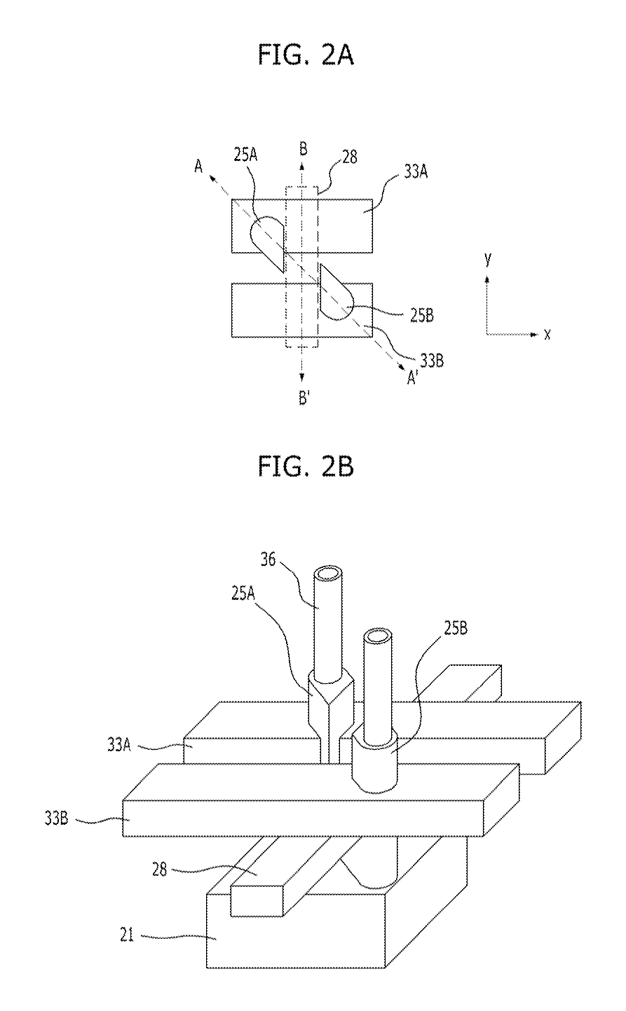

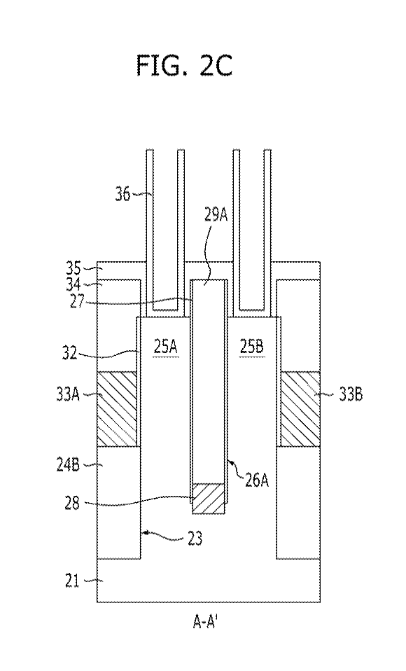

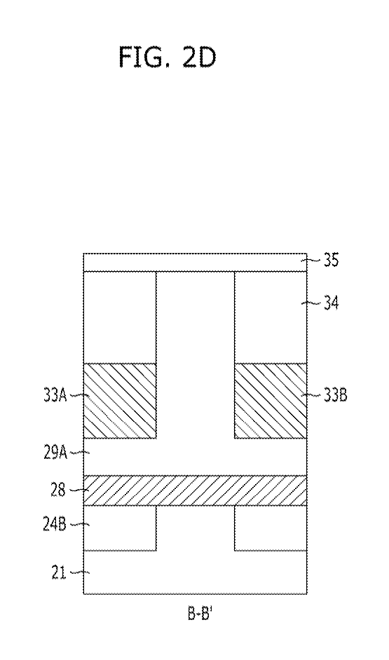

FIG. 2A is a plan view illustrating a semiconductor device in accordance with an exemplary embodiment of the present invention. FIG. 2B is a perspective view illustrating the semiconductor device in accordance with an embodiment of the present invention. FIG. 2C is a cross-sectional view showing the semiconductor device of FIG. 2A cut along a line A-A′. FIG. 2D is a cross-sectional view showing the semiconductor device of FIG. 2A cut along a line B-B′.

Referring to FIGS. 2A to 2D, a bit line trench 26A separating a first active region 25A and a second active region 25B from each other may be formed over a substrate 21. The first active region 25A and the second active region 25B may be formed in the shape of pillars. A buried bit line 28 partially filling the bit line trench 26A may be formed, and a first buried word line 33A surrounding the sidewalls of the first active region 25A may be formed. Also, a second buried word line 336 surrounding the sidewalls of the second active region 25B may be formed. On the upper portions of the first active region 25A and the second active region 25B, cylindrical storage nodes 36 may be formed respectively. The cylindrical storage nodes 36 may penetrate an etch stop layer 35, so that the cylindrical storage nodes 36 directly contact the upper surfaces of respective active regions 25A and 25B.

A device isolation pattern 24B may be formed between the first buried word line 33A and the second buried word line 33B. A bit line gap-filling layer 29A may be formed over the buried bit line 28. A word line gap-filling layer 34 may be formed over both the first buried word line 33A and the second buried word line 33B. A spacer 27 may be formed between the first active region 25A and the second active region 25B. The spacer 27 may expose a bottom portion of a sidewall of each bit line trench 26A in such a manner that the buried bit line 28 contacts the first active region 25A and the second active region 25B. The buried bit line 28 may cross the first buried word line 33A and the second buried word line 33B. For example, the buried bit line 28 may extend in a direction perpendicular to the direction that the first buried word line 33A and the second buried word line 33B extend. Also, the bit line gap-filling layer 29A and the device isolation pattern 24B may be included to insulate the first buried word line 33A and the second buried word line 33B from each other. The bit line gap-filling layer 29A may gap-fill an upper portion of the trench 26A over the buried bit line 28. The buried bit line 28, the first buried word line 33A and the second buried word line 33B may each include a metal layer. A gate insulation layer 32 may be formed on the sidewalls of the first active region 25A and the second active region 25B. More specifically, the gate insulation layer 32 may be formed between the first active region 25A and the first buried word line 33A and between the second active region 25B and the second buried word line 33B.

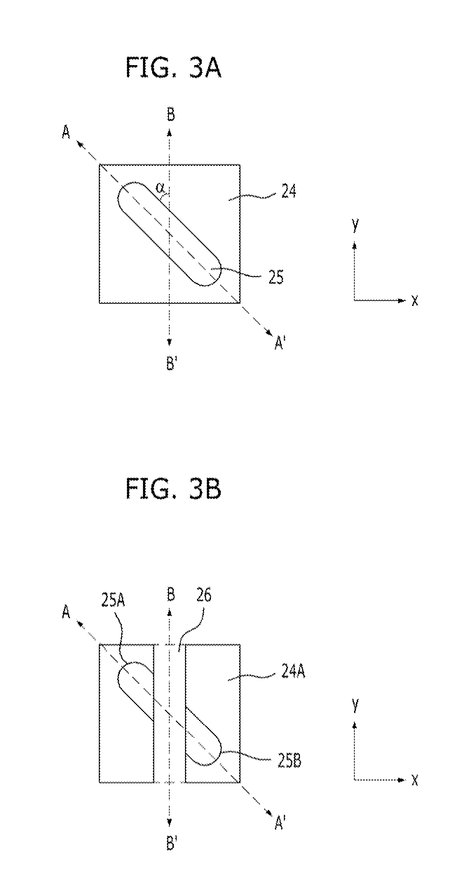

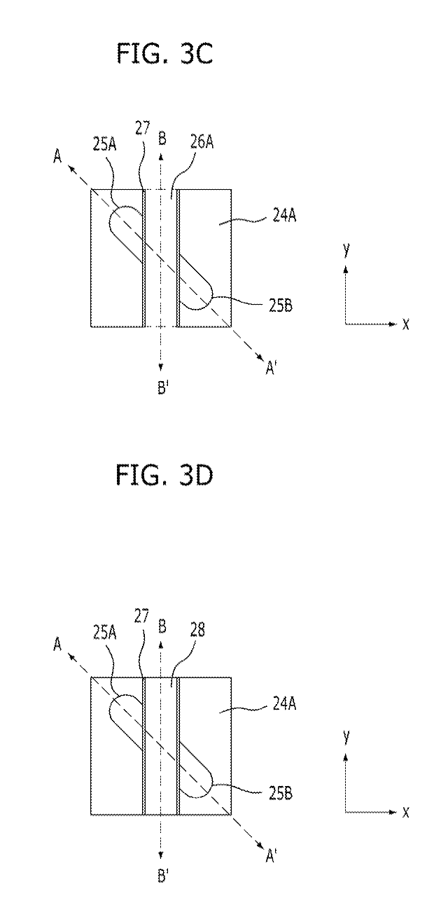

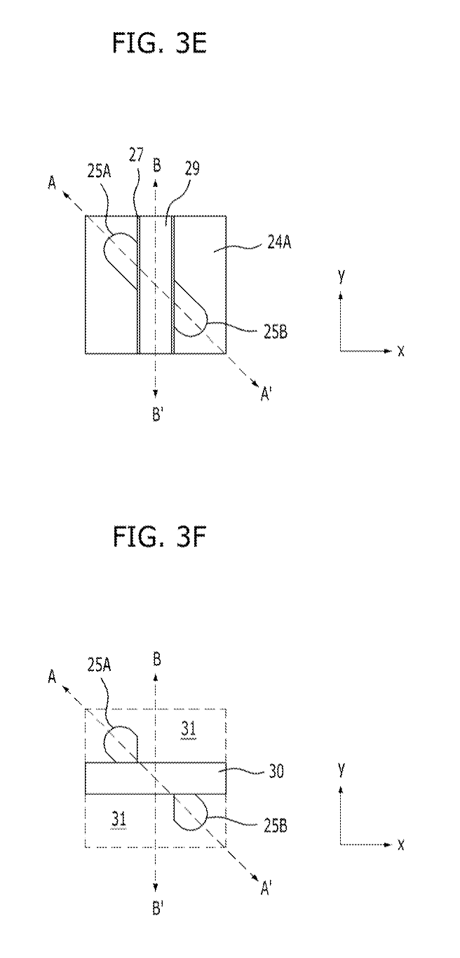

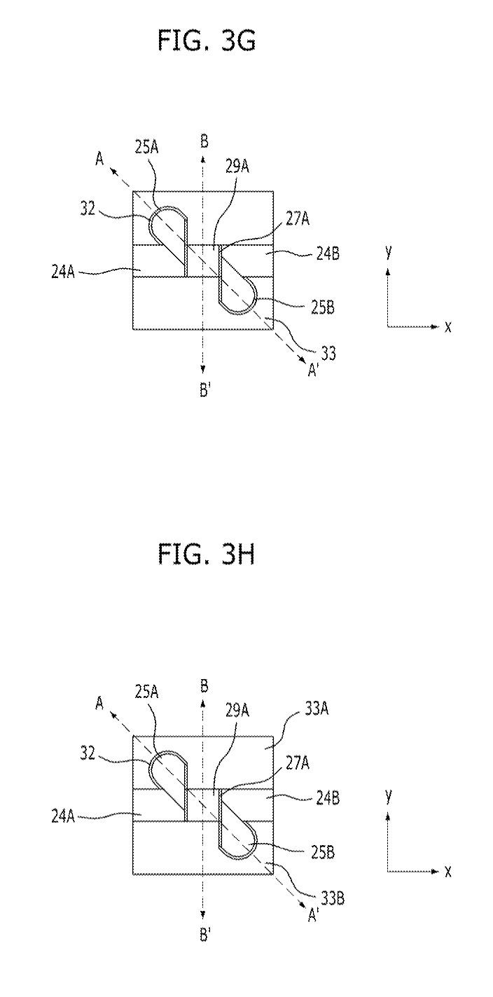

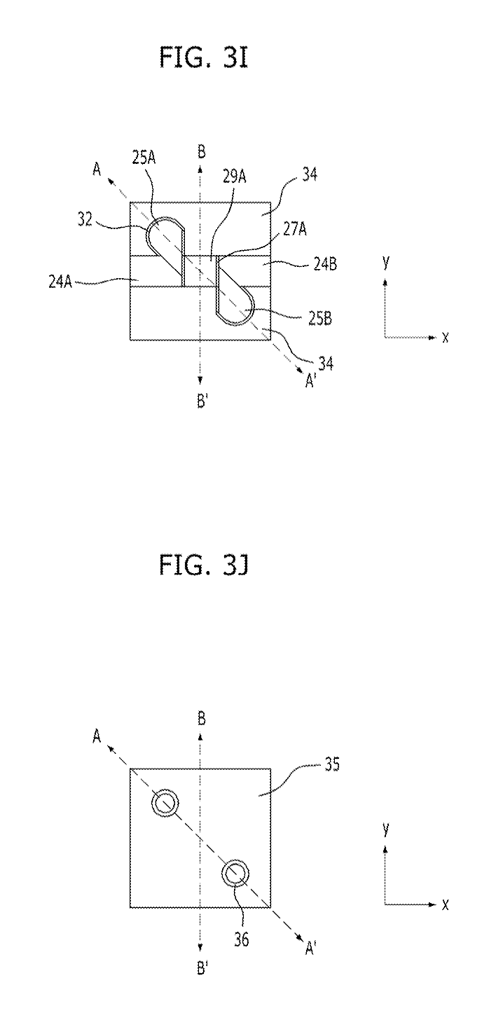

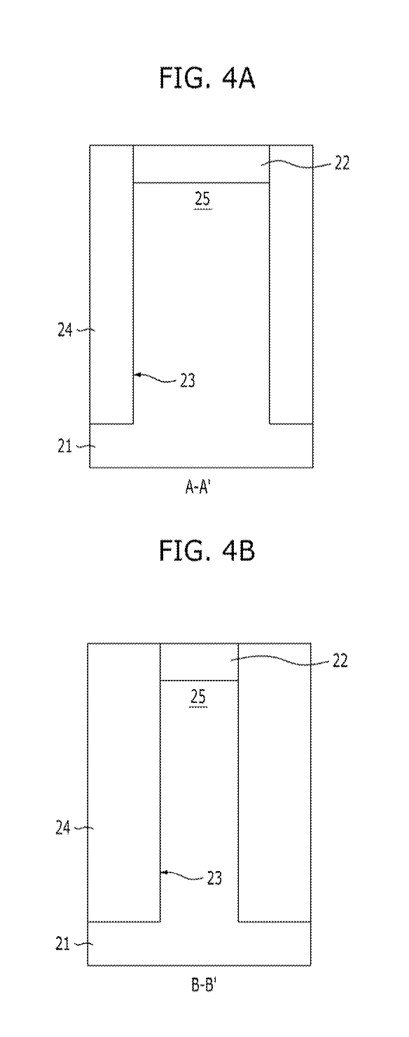

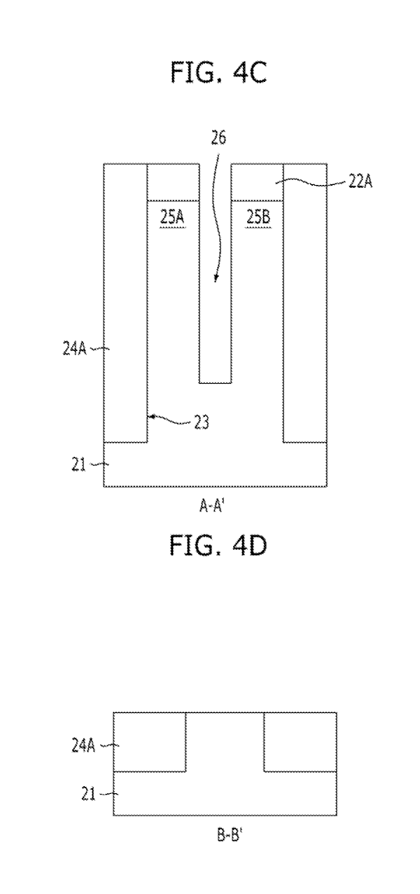

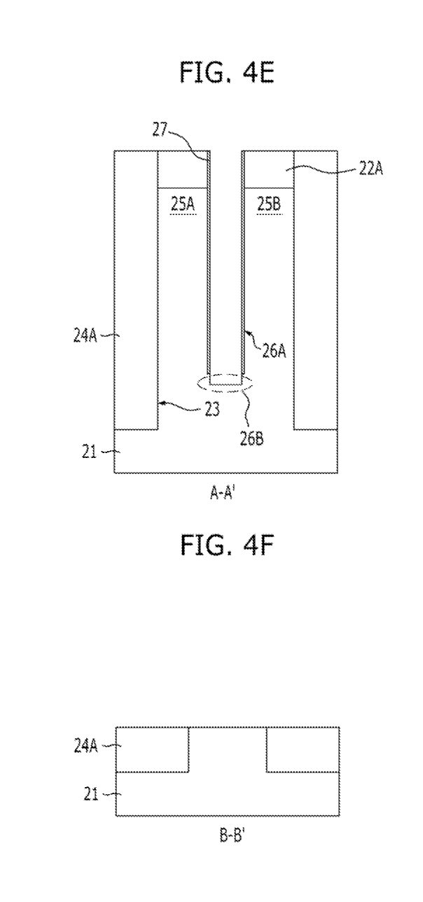

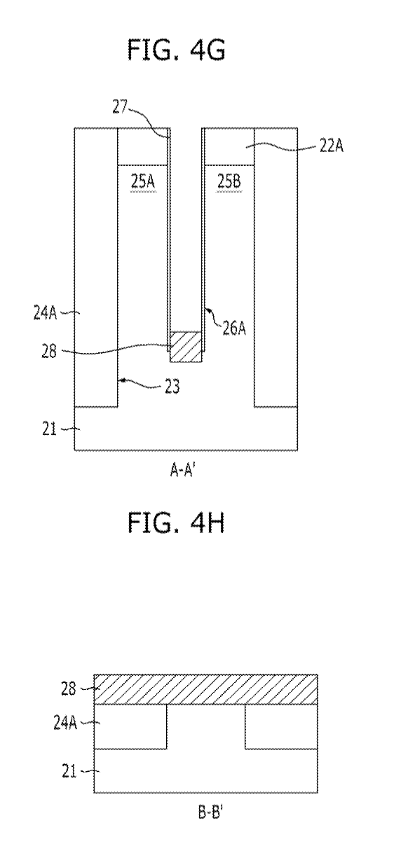

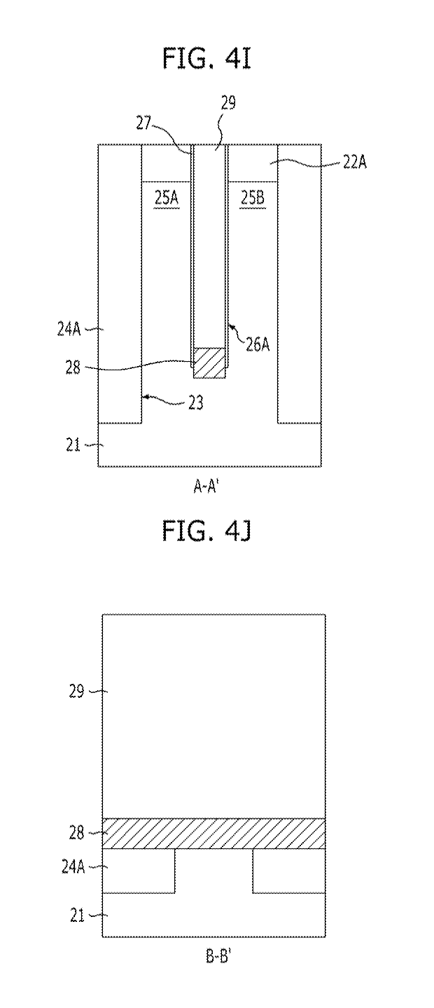

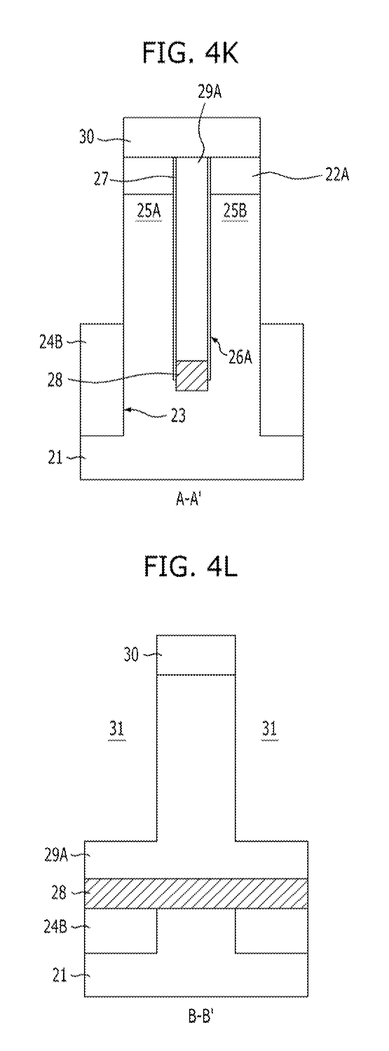

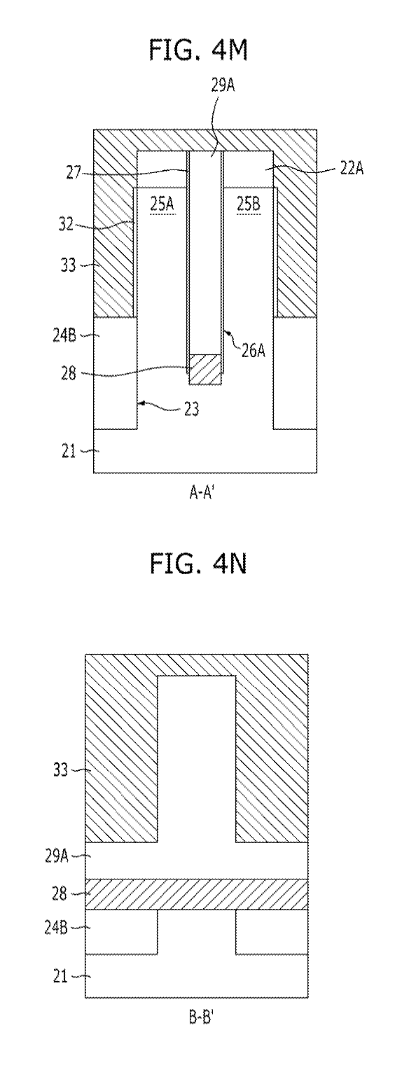

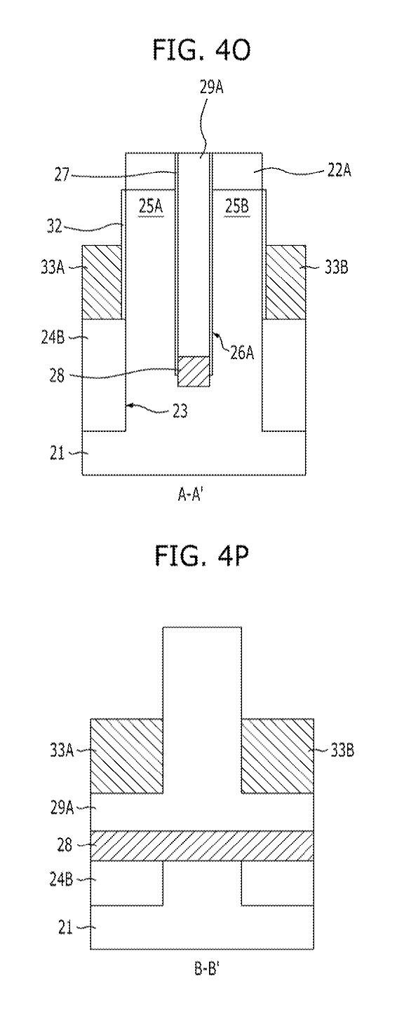

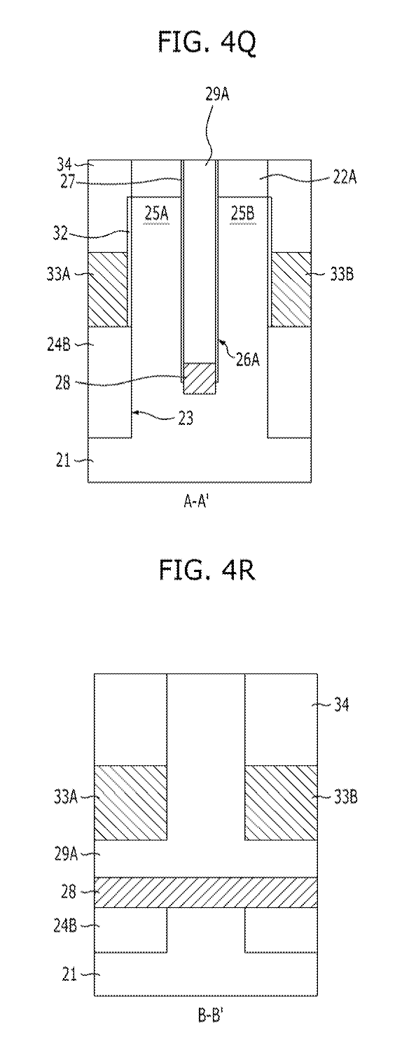

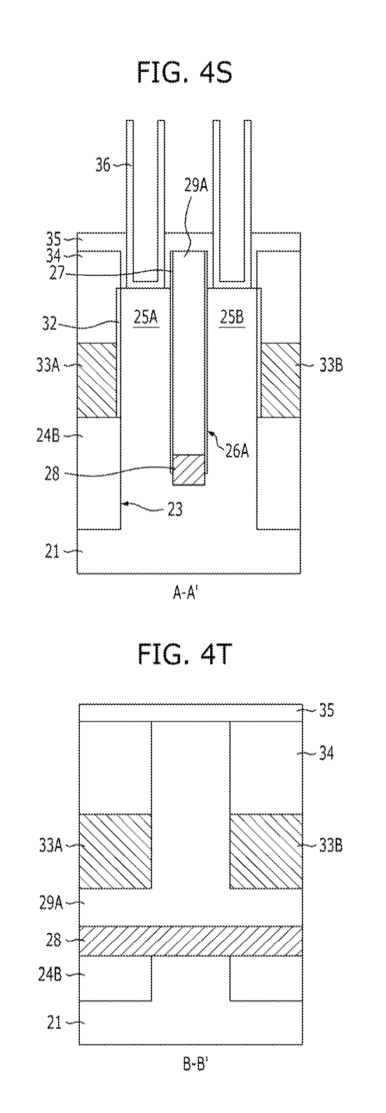

FIGS. 3A to 3J are plan views describing a method for fabricating a semiconductor device in accordance with an exemplary embodiment of the present invention. FIGS. 4A, 4C, 4E, 4G, 4I, 4K, 4M, 4O, 4Q and 4S are cross-sectional views showing the semiconductor device of FIGS. 3A to 3J cut along a line A-A′. FIGS. 4B, 4D, 4F, 4H, 4J, 4L, 4N, 4P, 4R and 4T are cross-sectional views showing the semiconductor device of FIGS. 3A to 3J cut along a line B-B′. In FIGS. 3A to 3J, a hard mask pattern 22 is not illustrated for the sake of convenience in description.

Referring to FIGS. 3A, 4A and 4B, a hard mask pattern 22 may be formed over the substrate 21. The hard mask pattern 22 may include a nitride layer.

A device isolation layer 24 may be formed by performing a device isolation process. The device isolation process may include a Shallow Trench Isolation (STI) process. First, the substrate 21 may be etched to a certain depth by using the hard mask pattern 22 as an etch barrier. As a result, trenches 23 may be formed. Subsequently, an insulation layer may be formed to gap-fill the trenches 23 and then a planarization process may be performed. The planarization process may include a Chemical Mechanical Polishing (CMP) process. The CMP process may be performed until the surface of the hard mask pattern 22 is exposed. The insulation layer may include an oxide layer, such as a Spin-On-Dielectric (SOD) layer. As a result, an active region 25 may be defined over the substrate 21. The active region 25 may be an island-type active region and it may be oriented at a certain angle with respect to a subsequently formed buried bit line 28. In a plan view, the active region 25 may be formed to be oriented at an angle a. For example, given an x-y plane as shown in FIGS. 3A to 3J, the active region 25 may be described as an island surrounded by a device isolation layer 24, which may be oriented from the second direction (y) at an angle of approximately 45°. Since the active region 25 may be oriented at a certain angle, the cell density may increase.

Referring to FIGS. 3B, 4C, and 4D, a bit line trench 26 may be formed by etching the active region 25 and the device isolation layer 24 in a direction crossing the active region 25. The bit line trench 26 and the active region 25 may cross each other, for example, at an angle of 45°. The bit line trench 26 may be a line pattern. That is, the bit line trench 26 may extend in a substantially straight line and maintain a substantially equal width.

After the bit line trench 26 is formed, the active region 25 may be divided into a first active region 25A and a second active region 25B. The first active region 25A and the second active region 25B may each have a pillar shape. Since they may have a pillar shape, the first active region 25A and the second active region 25B may each provide a vertical channel of a vertical cell. The resultant device isolation layer 24 after forming the bit line trench 26 is referred to as a device isolation layer pattern and denoted with a reference numeral ‘24A,’ and the resultant hard mask pattern 22 after forming the bit line trench 26 is denoted with a reference numeral ‘22A.’

Since the bit line trench 26, dividing the active region 25 into the first active region 25A and the second active region 25B, may be formed after the formation of the device isolation layer 24, the first active region 25A and the second active region 25B may be formed stably. Meanwhile, if active regions having a pillar shape are formed before the device isolation process, the active regions may collapse during the device isolation process.

Referring to FIGS. 3C, 4E, and 4F, a spacer 27 contacting both sidewalls of the bit line trench 26 may be formed. The spacer 27 may include an oxide layer. The spacer 27 may be formed by depositing an oxide layer and then performing an etch-back process. During the etch-back process for forming the spacer 27, an over-etch may occur and the depth of the bit line trench 26 may become deeper. As a result, a deep bit line trench 26A may be formed, and a bottom surface of the deep bit line trench 26A and a portion (see reference numeral ‘26B’) of each sidewall of the deep bit line trench 26A adjacent to the bottom surface may be exposed (Le., not covered by the spacer 27). The exposed bottom surface of the deep bit line trench 26A and the exposed portion 26B may allow the first active region 25A and the second active region 25B to contact a subsequently formed bit line.

Referring to FIGS. 3D, 4G, and 4H, a buried bit line 28 filling a portion of the deep bit line trench 26A may be formed. The buried bit line 28 may be formed by depositing a conductive layer and then performing an etch-back process. The conductive layer may include a barrier layer and a metal layer. The barrier layer may include a titanium layer, a titanium nitride layer, or a stacked layer of a titanium layer and a titanium nitride layer and the metal layer may include a tungsten layer.

The buried bit line 28 described above may contact the first active region 25A and the second active region 25B.

Referring to FIGS. 3E, 4I, and 4J, a gap-filling layer 29 gap-filling the upper portion of the deep bit line trench 26A over the buried bit line 28 may be formed. The gap-filling layer 29 may include an oxide layer. A planarization may be performed on the gap-filling layer 29 so that the gap-filling layer 29 only remains inside the deep bit line trench 26A over the buried bit line 28.

Referring to FIGS. 3F, 4K, and 4L, a word line trench mask 30 may be formed. The word line trench mask 30 may be a line pattern that covers a linear portion of the structure below while exposing two other linear portions of the structure below. Further, the word line trench mask 30 may be formed to cross over the buried bit line 28. For example, the word line trench mask 30 may be formed in a direction perpendicular to the direction in which the buried bit line 28 extends. The word line trench mask 30 may include a photoresist pattern.

The gap-filling layer 29, the hard mask pattern 22A, and the device isolation layer pattern 24A may be etched to a certain depth by using the word line trench mask 30 as an etch barrier. As a result, word line trenches 31 may be formed, and the word line trenches 31 may expose the sidewalls of the first active region 25A and the second active region 25B. A gap-filling layer pattern 29A may remain between the first active region 25A and the second active region 25B to insulate the two regions from each other. After the word line trenches 31 are formed, the device isolation layer pattern 24A may become shorter. Hereafter, the shorter device isolation layer pattern 24A will be referred to as a device isolation pattern 24B.

Referring to FIGS. 3G, 4M, and 4N, the word line trench mask 30 may be removed. Further, a gate insulation layer 32 may be formed on the sidewalls of the first active region 25A and the second active region 25B. The gate insulation layer 32 may be formed using a gate oxidation process.

A word line conductive layer 33 gap-filling the word line trenches 31 may be formed. The word line conductive layer 33 may include a metal layer. For example, the word line conductive layer 33 may include a tungsten layer.

Referring to FIGS. 3H, 4O, and 4P, the word line conductive layer 33 may be etched through an etch-back process. As a result, a first buried word line 33A and a second buried word line 33B may be formed. The first buried word line 33A and the second buried word line 33B may gap-fill a portion of each word line trench 31. The first buried word line 33A may be of a line shape that forms around the sidewalls of the first active region 25A. Also, the second buried word line 33B may be of a line shape that forms around the sidewalls of the second active region 25B. Accordingly, vertical channels may be formed.

Referring to FIGS. 3I, 4Q, and 4R, a word line gap-filling layer 34 gap-filling the upper portions of the word line trenches 31 over the first buried word line 33A and the second buried word line 33B may be formed. The word line gap-filling layer 34 may include an oxide layer. A planarization process may be performed onto the word line gap-filling layer 34 until the surface of the hard mask pattern 22A is exposed.

Referring to FIGS. 3J, 4S, and 4T, the hard mask pattern 22A may be removed. The hard mask pattern 22A may be removed through a stripping process.

Subsequently, a capacitor process may be performed. The capacitor process may include a storage node contact plug process, a storage node process, a dielectric layer process, and an upper electrode process.

After a formation of an etch stop layer 35, the upper portions of the first active region 25A and the second active region 25B may be exposed. Subsequently, storage nodes 36 may be formed, so that each one of the storage nodes 36 are coupled with one of the first active region 25A and the second active region 25B. Although not illustrated in the drawings, a capacitor may be formed through a subsequent process of forming a dielectric layer and an upper electrode. The storage node 36 may be a cylindrical storage node.

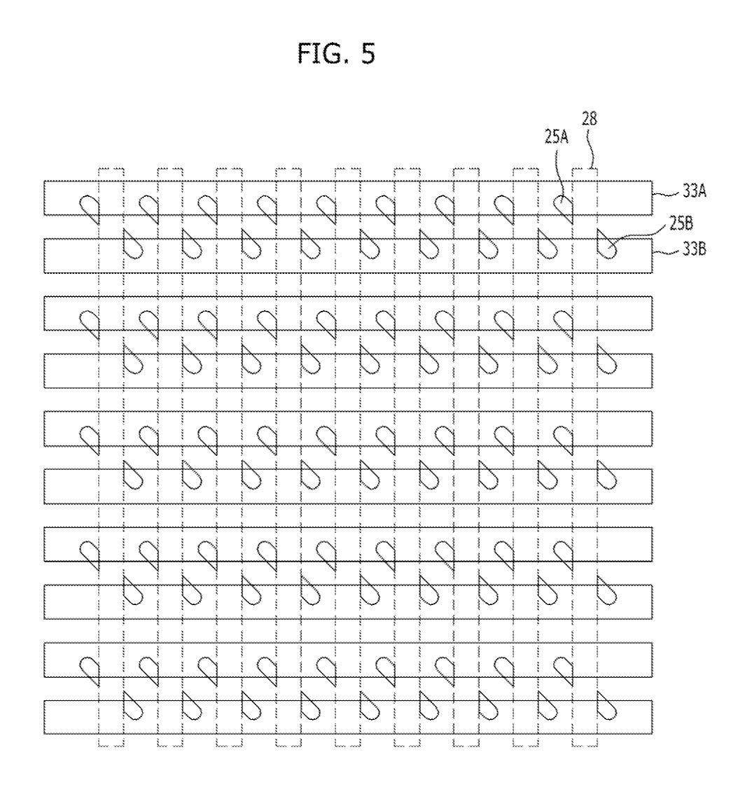

FIG. 5 is a plan view illustrating a cell array of a semiconductor device fabricated in accordance with an exemplary embodiment of the present invention.

According to the above-described embodiments of the present invention, cell density may increase as active regions are formed in the shape of islands and are oriented at an angle with respect to the direction of corresponding bit lines.

Also, a first active region and a second active region may stably be formed by dividing an active region into a first active region and a second active region after the device isolation layer is formed.

In addition, since buried bit lines and buried word lines are formed, a semiconductor device of a smaller design rule may be fabricated.

While the present invention has been described with respect to the specific embodiments, it will be apparent to those skilled in the art that various changes and modifications may be made without departing from the spirit and scope of the invention as defined in the following claims.

1-11. (canceled)

12. A semiconductor device, comprising:
a first active region and a second active region separated from each other by a trench;
a buried bit line filling a portion of the trench;
a first buried word line shaped around sidewalls of the first active region; and
a second buried word line shaped around sidewalls of the second active region; and
a first storage node directly contacted to an upper portion of the first active region and a second storage node directly contacted to an upper portion of the second active region.

13. The semiconductor device of claim 12, wherein the buried bit line crosses the first buried word line and the second buried word line.

14. The semiconductor device of claim 12, further comprising a device isolation pattern and a bit line gap-filling layer that insulate the first buried word line and the second buried word line from each other.

15. The semiconductor device of claim 14, wherein the bit line gap-filling layer gap-fills an upper portion of the trench over the buried bit line.

16. The semiconductor device of claim 12, wherein the first active region and the second active region have a pillar shape.

17. The semiconductor device of claim 12, wherein each of the buried bit line, the first buried word line, and the second buried word line includes a metal layer.

18. The semiconductor device of claim 12, further comprising:
a spacer arranged between the first active region and the buried bit line, and between the second active region and the buried bit line.

19. The semiconductor device of claim 18, wherein the spacer exposes a portion of a sidewall of the trench in such a manner that the first and second active regions contact the buried bit line.

20. (canceled)
